(19) United States
(12) Patent Application Publication
(10) Pub. No.: US 2026/0303318 A1
(43) Pub. Date: Oct. 1, 2026

(54) SIGNAL RECEIVING DEVICE

(71) Applicants: Yuan-Hsien Chen, New Taipei City (TW); Pen-Jui Peng, Taoyuan City (TW)

(72) Inventors: Yuan-Hsien Chen, New Taipei City (TW); Pen-Jui Peng, Taoyuan City (TW)

(73) Assignee: ITE Tech. Inc., Hsinchu (TW)

(21) Appl. No.: 19/213,969

(22) Filed: May 20, 2025

(30) Foreign Application Priority Data
Mar. 25, 2025 (TW) 114111101

(51) Int. Cl. H04L 7/02; H03K 17/56; H04L 25/03

(52) U.S. Cl. CPC H04L 7/02; H03K 17/56; H04L 25/03057

(57) ABSTRACT

A signal receiving device includes an analog front end circuit, a plurality of adders, a plurality of first splitter sets, a plurality of second splitter sets, a clock recovery circuit and a decision feedback equalizer. Each of the adders adds each of fist signal pairs with first parameters to generate each of a plurality of second signal pairs. Selected splitter sets of the second splitter sets, based on a calibrated parameter, sample corresponding second signal pair to generate first error information according to a reference voltage pair. Un-selected splitter sets of the second splitter set, based on a second parameter, samples corresponding second signal pair to generate a second error information according to the reference voltage pair. The clock recovery circuit and the decision feedback equalizer generate a plurality of received data corresponding to the input signal according to the first error information and the second error information, respectively.

### CROSS-REFERENCE TO RELATED APPLICATION

This application claims the priority benefit of Taiwan application serial no. 114111101, filed on Mar. 25, 2025. The entirety of the above-mentioned patent application is hereby incorporated by reference herein and made a part of this specification.

### BACKGROUND

### Technical Field

The disclosure relates to a signal receiving device, and more particularly to a signal receiving device that can effectively reduce a logic conflict between a clock recovery circuit and a feedback equalizer during a convergence process.

### Description of Related Art

In a conventional signal receiving device, a logic conflict may occur in a clock recovery circuit and a decision feedback equalizer during a convergence process because a convergence loop cannot be separated, and the clock recovery circuit may lock a sampling clock at an inappropriate phase.

In order to solve the logic conflict, in the prior art, an offset value for adjusting a sampling position of the clock recovery circuit may be added to a digital logic circuit. However, this approach may cause relatively severe jitter when the clock recovery circuit executes a locking action.

### SUMMARY

The disclosure provides a signal receiving device, which effectively reduces possibility of a logic conflict occurring in a clock recovery circuit and a feedback equalizer during a convergence process.

A signal receiving device of the disclosure includes an analog front end circuit, multiple adders, multiple first splitter sets, multiple second splitter sets, a clock recovery circuit, and a decision feedback equalizer. The analog front end circuit processes an input signal to generate multiple first signal pairs. The adders respectively receive the first signal pairs, and each of the adders adds each of the first signal pairs with multiple first parameters to generate each of multiple second signal pairs. The first splitter sets respectively correspond to the adders and sample the second signal pairs to respectively generate multiple sampled data according to a reference data pair based on a second parameter. The second splitter sets respectively correspond to the adders. Multiple selected splitter sets among the second splitter sets sample the corresponding second signal pairs to generate multiple first error information according to a reference voltage pair based on a correction parameter, and at least one unselected splitter set among the second splitter sets sample each of the corresponding second signal pairs to respectively generate second error information according to the reference voltage pair based on the second parameter. The clock recovery circuit and the decision feedback equalizer respectively generate multiple received data corresponding to the input signal according to the first error information and the second error information.

Based on the above, in the disclosure, a part of the second splitter sets sample each the corresponding second signal pairs to generate the first error information according to the reference voltage pair based on the second parameter, and another part of the second splitter sets sample the corresponding second signal pairs to respectively generate the second error information according to the reference voltage pair based on the correction parameter. The correction parameter is different from the second parameter. Furthermore, the clock recovery circuit and the decision feedback equalizer jointly generate the received data corresponding to the input signal respectively based on the second error information and the first error information. Therefore, through respectively providing different error information to the clock recovery circuit and the decision feedback equalizer, the clock recovery circuit and the decision feedback equalizer may have different convergence information, and the logic conflict may not occur.

### BRIEF DESCRIPTION OF THE DRAWINGS

FIG. 1 is a schematic diagram of a signal receiving device according to an embodiment of the disclosure.

FIG. 2 is a schematic diagram of an implementation manner of a splitter set in a signal receiving device according to an embodiment of the disclosure.

FIG. 3 is a schematic diagram of a three-level voltage split waveform of the splitter set in the embodiment of FIG. 2.

FIG. 4 is a schematic diagram of an implementation manner of a splitter set in a signal receiving device according to an embodiment of the disclosure.

FIG. 5 is a schematic diagram of a three-level voltage split waveform of the splitter set in the embodiment of FIG. 4.

### DESCRIPTION OF THE EMBODIMENTS

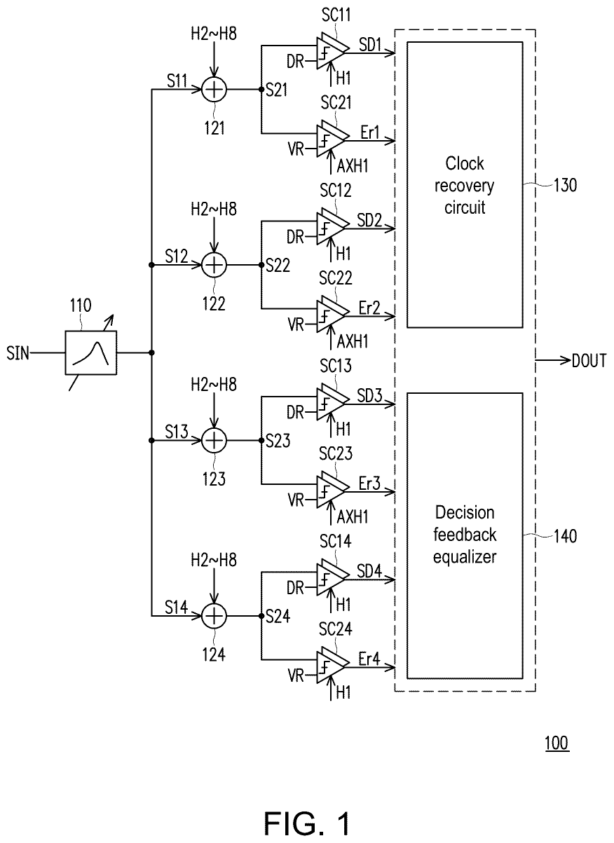

Please refer to FIG. 1. FIG. 1 is a schematic diagram of a signal receiving device according to an embodiment of the disclosure. A signal receiving device 100 includes an analog front end circuit 110, adders 121 to 124, splitter sets SC11 to SC14 and SC21 to SC24, a clock recovery circuit 130, and a decision feedback equalizer 140. The analog front end circuit 110 receives an input signal SIN and is used to process the input signal SIN to generate multiple signal pairs S11 to S14. In the embodiment, the signal pairs S11 to S14 may respectively have different phases. Specifically, the signal pairs S11 to S14 may be signal pairs of four phases. In addition, each of the signal pairs S11 to S14 may be a differential signal pair, that is, each of the signal pairs S11 to S14 may have a first signal and a second signal that are differential signals to each other.

In the embodiment, the analog front end circuit 110 may perform a continuous-time linear equalization (CTLE) process on the received input signal SIN, and execute a variable gain amplification (VGA) action to generate the signal pairs S11 to S14.

In addition, the adders 121 to 124 respectively receive the signal pairs S11 to S14. The adders 121 to 124 are respectively used to add the signal pairs S11 to S14 with parameters H2 to H8 to respectively generate the signal pairs S21 to S24. Likewise, each of the signal pairs S21 to S24 may also be a differential signal pair.

In the embodiment, the splitter sets SC11 to SC14 respectively correspond to the adders 121 to 124. The splitter sets SC11 to SC14 may sample the corresponding signal pairs S21 to S24 to respectively generate multiple sampled data SD1 to SD4 according to a reference data pair DR based on a parameter H1. On the other hand, the splitter sets SC21 to SC24 also respectively correspond to the adders 121 to 124 and may be divided into selected splitter sets and unselected splitter sets. In the embodiment, the splitter set SC24 is the unselected splitter set, and the splitter sets SC21 to SC23 are the selected splitter sets. The splitter sets SC21 to SC23 jointly receive a correction parameter AXH1 and a reference voltage pair VR, and respectively receive the signal pairs S21 to S23. The splitter sets SC21 to SC23 respectively sample the corresponding signal pairs S21 to S23 to generate error information Er1 to Er3 according to the reference voltage pair VR based on the correction parameter AXH1. The splitter set SC24 receives the parameter H1 and the reference voltage pair VR, and receives the signal pair S24. The splitter set SC24 samples the corresponding signal pair S24 to generate error information Er4 according to the reference voltage pair VR based on the parameter H1.

In the embodiment, the correction parameter AXH1 may be equal to the parameter H1 multiplied by a coefficient A, where the coefficient A is a real number not equal to 1.

It is worth noting that in the embodiment, the error information Er4 is used as convergence information of the decision feedback equalizer 140, and the error information Er1 to Er3 are used as convergence information of the clock recovery circuit 130. Specifically, the signal receiving device 100 of the embodiment uses the error information Er1 to Er3 output by the three-way splitter sets SC21 to SC23 among the four-way splitter sets SC21 to SC24 as the convergence information of the clock recovery circuit 130, and uses the error information Er4 output by the one-way splitter set SC24 among the four-way splitter sets SC21 to SC24 as the convergence information of the decision feedback equalizer 140. In this way, the convergence information of the clock recovery circuit 130 and the decision feedback equalizer 140 are different and not conflicting. In addition, in the embodiment, a phase locked by the clock recovery circuit 130 may be adjusted through changing the size of the coefficient A. The coefficient A may be greater than 1 or less than 1, but not equal to 1.

In the embodiment, the clock recovery circuit 130 may be a baud rate clock and data recovery circuit.

It is worth noting that in other embodiments of the disclosure, the selected splitters may be any three of the four-way splitter sets SC21 to SC24 and are not necessarily limited to the splitter sets SC21 to SC23. Furthermore, the number of unselected splitters is not limited to one. In some embodiments of the disclosure, the unselected splitters may also be any two of the four splitter sets SC21 to SC24 without any specific limitation.

Incidentally, the circuit architectures of the adders 121 to 124, the clock recovery circuit 130, and the decision feedback equalizer 140 of the disclosure may all be implemented by applying circuit architectures well known to persons skilled in the art without any fixed limitation.

In addition, the parameters H1 to H4 in the embodiment of the disclosure may be provided by the clock recovery circuit 130 and the decision feedback equalizer 140. The clock recovery circuit 130 and the decision feedback equalizer 140 jointly generate an output signal DOUT.

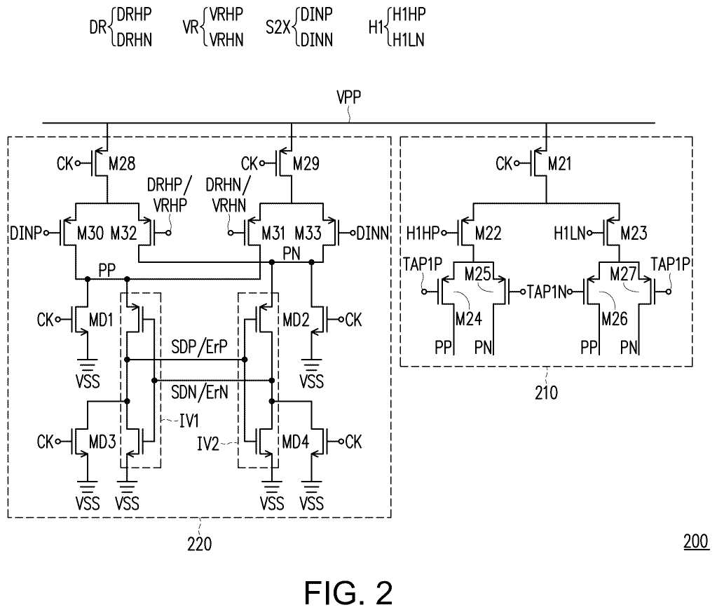

Please refer to FIG. 2. FIG. 2 is a schematic diagram of an implementation manner of a splitter set in a signal receiving device according to an embodiment of the disclosure. A splitter set 200 is a single feedback end splitter set. The splitter set 200 may be applied to any one of the splitter sets SC11 to SC24 in the embodiment of FIG. 1. The splitter set 200 includes a first partial circuit 210 and a second partial circuit 220. The first partial circuit 210 is used to provide a first bias PP and a second bias PN according to the parameter H1 and a correction parameter. The correction parameter is equal to a product of the parameter H1 and the coefficient A, and the coefficient A may be provided through a sub-parameter TAP1P. The second partial circuit 220 is coupled to the first partial circuit 210 and compares a corresponding signal pair S2X with the reference data pair DR or the reference voltage pair VR to generate corresponding sub-sampled data SDP or SDN or sub-error information ErP or ErN based on the first bias PP and the second bias PN.

In the embodiment, the first partial circuit 210 includes transistors M21 to M27, wherein the transistors M22 and M23 form a first transistor pair, the transistors M24 and M25 form a second transistor pair, and transistors M26 and M27 form a third transistor pair. A first terminal of the transistor M21 receives a power supply voltage VPP, a second terminal of the transistor M21 is coupled to the first transistor pair, and a control terminal of the transistor M21 receives a clock signal CK. In the first transistor pair, first terminals of the transistors M22 and M23 are coupled to the second terminal of the transistor M21, and the transistors M22 and M23 are respectively controlled by sub-parameters H1HP and H1LN in the parameter H1, wherein the su b-parameters H1HP and H1LN form a sub-parameter pair. Second terminals of the transistors M22 and M23 are respectively coupled to the second transistor pair and the third transistor pair.

In the second transistor pair, first terminals of the transistors M24 and M25 are coupled to the second terminal of the transistor M22, and the transistors M24 and M25 are respectively controlled by sub-parameters TAP1P and TAP1N, wherein the sub-parameters TAP1P and TAP1N form a sub-parameter pair, and the sub-parameters TAP1P and TAP1N are generated according to the correction parameter. Second terminals of the transistors M24 and M25 respectively generate the first bias PP and the second bias PN.

In the third transistor pair, first terminals of the transistors M26 and M27 are coupled to the second terminal of the transistor M23, the transistors M26 and M27 are respectively controlled by the sub-parameters TAP1N and TAP1P, and second terminals of the transistors M26 and M27 respectively generate the first bias PP and the second bias PN.

In the embodiment, the sub-parameters TAP1N and TAP1P may complement each other.

In addition, in the embodiment, one of the transistors M22 and M23 may be turned on according to the sub-parameters H1HP and H1LN, and the other one may be turned off. Alternatively, the transistors M22 and M23 may be turned off at the same time according to the sub-parameters H1HP and H1LN. One of the transistors M24 and M25 may be turned on according to the sub-parameters TAP1N and TAP1P, and the other one may be turned off. One of the transistors M26 and M27 may be turned on according to the sub-parameters TAP1N and TAP1P, and the other one may be turned off.

On the other hand, the second partial circuit 220 includes transistors M28 to M33, inverters IV1 and IV2, and multiple pull-down transistors MD1 to MD4. First terminals of the transistors M28 and M29 jointly receive the power supply voltage VPP, and the transistors M28 and M29 are jointly controlled by the clock signal CK. A second terminal of the transistor M28 is coupled to transistors M30 and M32, and a second terminal of the transistor M29 is coupled to transistors M31 and M33.

A first terminal of the transistor M30 is coupled to the second terminal of the transistor M28, the transistor M30 is controlled by a first sub-signal DINP of the signal pair S2X, and a second terminal of the transistor M30 receives the first bias PP and serves as a power supply terminal of the inverter IV1. A first terminal of the transistor M31 is coupled to the second terminal of the transistor M29, the transistor M31 is controlled by sub-reference data DRHN of the reference data pair DR or sub-reference voltage VRHN of the reference voltage pair VR, and a second terminal of the transistor M31 is coupled to the second terminal of the transistor M30.

A first terminal of the transistor M33 is coupled to the second terminal of the transistor M29, the transistor M33 is controlled by a second sub-signal DINN of the signal pair S2X, a second terminal of the transistor M33 receives the second bias PN and serves as a power supply terminal of the inverter IV2. A first terminal of the transistor M32 is coupled to the second terminal of the transistor M28, the transistor M32 is controlled by sub-reference data DRHP of the reference data pair DR or sub-reference voltage VRHP of the reference voltage pair VR, and a second terminal of the transistor M32 is coupled to the second terminal of the transistor M33.

The inverter IV1 is coupled between the second terminals of the transistors M32 and M33 and a reference ground voltage VSS, and the inverter IV2 is coupled between the second terminals of the transistors M31 and M34 and the reference ground voltage VSS. An output terminal of the inverter IV1 is coupled to an input terminal of the inverter IV2 and generates sub-sampled data SDP of the sampled data or the sub-error information ErP of the error information. An output terminal of the inverter IV2 is coupled to an input terminal of the inverter IV1 and generates the sub-sampled data SDN of the sampled data or the sub-error information ErN of the error information. The inverters IV1 and IV2 may form a latch circuit and latch the generated sub-sampled data SDP and SDN or sub-error information ErP and ErN.

Incidentally, the pull-down transistors MD1 and MD2 are coupled between the second terminals of the transistors M30 and M32 and the reference ground voltage VSS, and are controlled by the clock signal CK. When the pull-down transistors MD1 and MD2 are turned on according to the clock signal CK, voltages at the second terminals of the transistors M30 and M32 may be reset to the reference ground voltage VSS. The pull-down transistors MD3 and MD4 are coupled between the output terminals of the inverters IV1 and IV2 and the reference ground voltage VSS, and are controlled by the clock signal CK. When the pull-down transistors MD3 and MD4 are turned on according to the clock signal CK, the data latched in the latch formed by the inverters IV1 and IV2 of the transistors M30 and M32 may be reset.

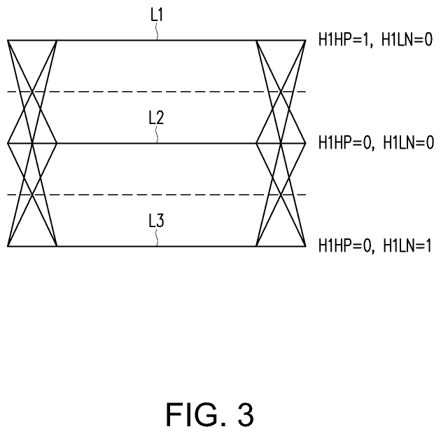

Please refer to FIG. 3. FIG. 3 is a schematic diagram of a three-level voltage split waveform of the splitter set in the embodiment of FIG. 2. When a data receiving device of the disclosure is applied to coding and decoding technology of 3-level pulse amplitude modulation (PAM- 3), when the sub-parameters H1HP and H1LN respectively have logic values 1 and 0, a highest voltage level L1 may be corresponded; when the sub-parameters H1HP and H1LN both have logic values 0, a middle voltage level L2 may be corresponded; and when the sub-parameters H1HP and H1LN respectively have logic values 0 and 1, a lowest voltage level L3 may be corresponded.

According to the voltage levels L1 to L3, encoding and decoding actions of 3-level pulse amplitude modulation may be completed.

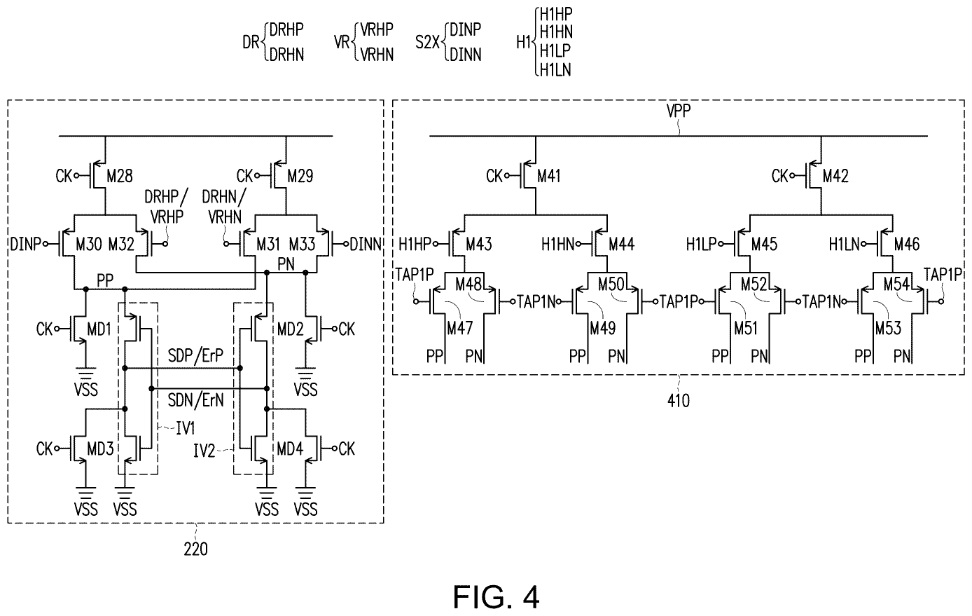

Please refer to FIG. 4. FIG. 4 is a schematic diagram of an implementation manner of a splitter set in a signal receiving device according to an embodiment of the disclosure. A splitter set 400 is a double feedback end splitter set. The splitter set 400 may also be applied to any one of the splitter sets SC11 to SC24 in the embodiment of FIG. 1. The splitter set 400 includes a first partial circuit 410 and the second partial circuit 220.

In the implementation manner, the second partial circuit 220 in the splitter set 400 is the same as the second partial circuit 220 in the implementation manner of FIG. 2, and the relevant details are not repeated herein.

In addition, in the implementation manner, the first partial circuit 410 is constructed by adopting a double feedback end manner. The first partial circuit 410 includes transistors M41 to M54. The transistors M41 and M42 form a transistor pair, wherein first terminals of the transistors M41 and M42 jointly receive the power supply voltage VPP and control terminals of the transistors M41 and M42 jointly receive the clock signal CK. The transistors M43 and M44 form a transistor pair and are coupled to the second terminal of the transistor M41. A control terminal of the transistor M43 receives the sub-parameter H1HP of the parameter H1, and a control terminal of the transistor M44 receives a sub-parameter pair H1HN of the parameter H1. The transistors M45 and M46 form a transistor pair and are coupled to the second terminal of the transistor M42. A control terminal of the transistor M45 receives a sub-parameter pair H1LP of the parameter H1, and a control terminal of the transistor M46 receives the sub-parameter H1LN of the parameter H1.

The transistors M47 to M54 form a transistor pair in pairs. The transistors M47 and M48 are coupled to the second terminal of the transistor M43, control terminals of the transistors M47 and M48 respectively receive the sub-parameters TAP1P and TAP1N, and second terminals of the transistors M47 and M48 respectively provide the first bias PP and the second bias PN. The transistors M49 and M50 are coupled to the second terminal of the transistor M44, control terminals of the transistors M49 and M50 respectively receive the sub-parameters TAP1N and TAP1P, and second terminals of the transistors M49 and M50 respectively provide the first bias PP and the second bias PN.

On the other hand, the transistors M51 and M52 are coupled to the second terminal of the transistor M45, control terminals of the transistors M51 and M52 respectively receive the sub-parameters TAP1P and TAP1N, and second terminals of the transistors M51 and M52 respectively provide the first bias PP and the second bias PN. The transistors M53 and M54 are coupled to the second terminal of the transistor M46, control terminals of the transistors M53 and M54 respectively receive the sub-parameters TAP1N and TAP1P, and second terminals of the transistors M53 and M54 respectively provide the first bias PP and the second bias PN.

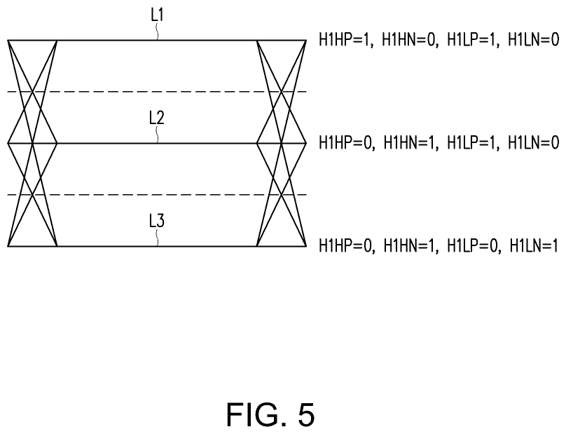

Please refer to FIG. 5. FIG. 5 is a schematic diagram of a three-level voltage split waveform of the splitter set in the embodiment of FIG. 4. When a data receiving device of the disclosure is applied to coding and decoding technology of 3-level pulse amplitude modulation (PAM-3), when the sub-parameters H1HP, H1HN, H1LP, and H1LN respectively have logic values 1, 0, 1, and 0, the highest voltage level L1 may be corresponded; when the sub-parameters H1HP, H1HN, H1LP, and H1LN respectively have logic values 0, 1, 1, and 0, the middle voltage level L2 may be corresponded; and when the sub-parameters H1HP, H1HN, H1LP, and H1LN respectively have logic values of 0, 1, 0, and 1, the lowest voltage level L3 may be corresponded.

In summary, the signal receiving device of the disclosure provides different error information respectively to the clock recovery circuit and the decision feedback equalizer, so that the clock recovery circuit and the decision feedback equalizer may have different convergence information. In this way, a logic operation conflict between the clock recovery circuit and the decision feedback equalizer may be prevented, which can effectively improve the working efficiency of the signal receiving device.

What is claimed is:

1. A signal receiving device, comprising:
an analog front end circuit, processing an input signal to generate a plurality of first signal pairs;
a plurality of adders, respectively receiving the first signal pairs, each of the adders adding each of the first signal pairs with a plurality of first parameters to generate each of a plurality of second signal pairs;
a plurality of first splitter sets, respectively corresponding to the adders and sampling the second signal pairs to respectively generate a plurality of sampled data according to a reference data pair based on a second parameter;
a plurality of second splitter sets, respectively corresponding to the adders, a plurality of selected splitter sets among the second splitter sets sampling the corresponding second signal pairs to respectively generate a plurality of first error information according to a reference voltage pair based on a correction parameter, and at least one unselected splitter set among the second splitter sets sampling each of the corresponding second signal pairs to respectively generate second error information according to the reference voltage pair based on the second parameter; and
a clock recovery circuit and a decision feedback equalizer, respectively generating a plurality of received data corresponding to the input signal according to the first error information and the second error information.

2. The signal receiving device according to claim 1, wherein the correction parameter is A times the second parameter, where A is a positive real number not equal to 1.

3. The signal receiving device according to claim 1, wherein the second error information is used as convergence information of the decision feedback equalizer, and the first error information is used as convergence information of the clock recovery circuit.

4. The signal receiving device according to claim 1, wherein the first signals have different phases.

5. The signal receiving device according to claim 1, wherein the first signal pair and the second signal pair are both differential signal pairs.

6. The signal receiving device according to claim 1, wherein the reference data pair comprises first reference data and second reference data, the first reference data and the second reference data complement each other, the reference voltage pair comprises a first reference voltage and a second reference voltage, and the first reference voltage is greater than the second reference voltage.

7. The signal receiving device according to claim 1, wherein each of the first splitter sets and the second splitter sets comprises:
a first partial circuit, used to provide a first bias and a second bias according to the second parameter and the correction parameter; and
a second partial circuit, coupled to the first partial circuit and comparing each of the corresponding second signal pairs with the reference data pair or the reference voltage pair to generate each of the corresponding sampled data, the second error information, or each of the first error information based on the first bias and the second bias.

8. The signal receiving device according to claim 7, wherein the first partial circuit comprises:
a first transistor pair, receiving a power supply voltage and turned on or off according to a clock signal;
a second transistor pair and a third transistor pair, coupled to the first transistor pair, wherein the second transistor pair selects a turned-on path according to a first sub-parameter pair of the second parameter, and the third transistor pair selects a turned-on path according to a second sub-parameter pair of the second parameter; and
a fourth transistor pair to a seventh transistor pair, wherein the fourth transistor pair and the fifth transistor pair are coupled to the second transistor pair, the sixth transistor pair and the seventh transistor pair are coupled to the third transistor pair, and each of the fourth transistor pair to the seventh transistor pair selects a turned-on path according to a sub-parameter pair generated by the correction parameter to generate the first bias and the second bias.

9. The signal receiving device according to claim 7, wherein the first partial circuit comprises:
a first transistor, receiving a power supply voltage and turned on or off according to a clock signal;
a first transistor pair, coupled to the first transistor, wherein the first transistor pair selects a turned-on path according to a first sub-parameter pair of the second parameter;
a second transistor pair and a third transistor pair, coupled to the first transistor pair and selecting a turned-on path according to a sub-parameter pair of the correction parameter to generate the first bias and the second bias.

10. The signal receiving device according to claim 7, wherein the second partial circuit comprises:
a first transistor and a second transistor, receiving a power supply voltage and turned on or off according to a clock signal;
a third transistor and a fourth transistor, having first terminals respectively coupled to the first transistor and the second transistor, wherein the third transistor is controlled by a first sub-signal of each of the second signal pairs, the fourth transistor is controlled by first sub-reference data of the reference data pair or a first sub-reference voltage of the reference voltage pair, and second terminals of the third transistor and the fourth transistor are coupled to each other and receive the first bias;
a fifth transistor and a sixth transistor, having first terminals respectively coupled to the first transistor and the second transistor, wherein the fifth transistor is controlled by a first sub-signal of each of the second signal pairs, the fourth transistor is controlled by a first sub-reference data of the reference data pair or a first sub-reference voltage of the reference voltage pair, and second terminals of the fifth transistor and the sixth transistor are coupled to each other and receive the second bias;
a first inverter and a second inverter, wherein a power supply terminal of the first inverter is coupled to the second terminals of the third transistor and the fourth transistor, a power supply terminal of the second inverter is coupled to the second terminals of the fifth transistor and the sixth transistor, an output terminal of the first inverter is coupled to an input terminal of the second inverter and generates first sub-sampled data of each of the sampled data, first sub-error information of each of the first error information, or first sub-error information of the second error information, and an input terminal of the first inverter is coupled to an output terminal of the second inverter and generates second sub-sampled data of each of the sampled data, second sub-error information of each of the first error information, or second sub-error information of the second error information.
